(19) United States
(12) Patent Application Publication
(10) Pub. No.: US 2024/0045100 A1
(43) Pub. Date: Feb. 8, 2024

(54) Programmable Structured Light Generator, Photoelectric Device Having Same, And Manufacturing Method

(71) Applicant: Shenzhen Berxel Photonics Co., Ltd., Shenzhen (CN)

(72) Inventors: Chenyang Wu, Shenzhen (CN); Xuanlun Huang, Shenzhen (CN); Yipeng Ji, Shenzhen (CN); Jiaxing Wang, Shenzhen (CN); Constance Jui-Hua Chang-Hasnain, Shenzhen (CN)

(21) Appl. No.: 18/485,794

(22) Filed: Oct. 12, 2023

(30) Foreign Application Priority Data
Aug. 23, 2023 (CN) 202311069822.0

(51) Int. Cl. G02B 1/00; H01S 5/042; H01S 5/42; G02B 27/30

(52) U.S. Cl. CPC G02B 1/002; H01S 5/042; H01S 5/423; G02B 27/30

(57) ABSTRACT

A programmable structured light generator, a photoelectric device having same, and a manufacturing method. The structured light generator includes: a laser module, wherein the laser module includes a programmable controller and an individually addressable vertical cavity surface emitting laser array (VCSEL), and the programmable controller is used for controlling light spot position coding of the VCSEL array; a collimation module, disposed at a light source emitter of the VCSEL array, wherein the collimation module is used for collimating emergent light of the VCSEL array; and a metasurface module, disposed on an emitted light focal plane path, wherein the metasurface module is used for projecting a programmable structured light speckle dot matrix pattern in a far field.

### CROSS-REFERENCE TO RELATED APPLICATION(S)

The present application claims priority to Chinese patent application No. 202311069822.0, filed on Aug. 23, 2023, the entire contents of which are incorporated herein by reference.

### TECHNICAL FIELD

The present disclosure generally relates to the technical field of photoelectric devices, and in particular to a programmable structured light generator, a photoelectric device having same, and a manufacturing method.

### BACKGROUND

With the emergence of scenarios with high security requirements such as facial recognition access control and facial payment, 3D structured light stereo imaging technology was born at the right moment. The principle of the imaging technology is that a transmitting end transmits a pattern with a coding rule and projects the pattern onto a measured object, and then a receiving end detects the three-dimensional topography of the measured object according to the pattern reflected by the measured object and by means of calculating a speckle deformation condition of structured light.

Structured light projectors typically employ Dammann gratings as DOEs (Diffractive Optical Elements, DOE), and the generated speckles patterns are normally regular with rectangular or symmetrical shapes instead of random pattern. Traditional DOE used for generating structured light are obtained by using a scalar diffraction theory and by means of iterative algorithm optimization design, but when the period of the DOE is less than or equal to an incident wavelength, the scalar diffraction theory generates a relatively large deviation from the actual situation, so that the imaging quality of the structured light is significantly reduced; Furthermore, to achieve a sufficient number and density of laser speckle distributions, a single projector typically needs to utilize a randomly arranged array of several hundred vertical cavity surface emitting lasers (VCSEL) as a basic encoding pattern, which is then duplicated and spliced by DOEs to generate laser speckle coding pattern with more speckle points and a larger field of view (FOV). This significantly increases manufacturing costs. Moreover, a laser speckle code pattern is formed by copying and splicing basic code patterns, which are generated by a laser random array, therefore not only the coding and decoding algorithms are complex, but similar blocks also appear in the code pattern, that is, a plurality of speckle point distribution modes are completely consistent or in similar areas, thereby easily leading to feature point matching errors during decoding, and seriously reducing the calculation precision, thus having limitations.

### SUMMARY

In view of the above defects or deficiencies in the related art, it is desirable to provide a programmable structured light generator, a photoelectric device having same, and a manufacturing method. Therefore, a speckle code pattern may be efficiently and flexibly controlled, the calculation precision is improved, and the reliability is high.

In a first aspect, the present disclosure provides a programmable structured light generator, wherein the programmable structured light generator includes: a laser module, wherein the laser module includes a programmable controller and an individually addressable vertical cavity surface emitting laser array, and the programmable controller is used for controlling light spot position codes of the VCSEL array; a collimation module, disposed at a light outlet of the VCSEL array, wherein the collimation module is used for collimating emergent light of the VCSEL array; and a metasurface module, disposed on an emergent light focal plane path, wherein the metasurface module is used for projecting a programmable structured light speckle dot matrix pattern in a far field, and copy expansion codes of a single point in the structured light speckle dot matrix pattern are in one-to-one correspondence with the light spot position codes in the VCSEL array.

In one embodiment, the metasurface module includes a metasurface structure array, and the metasurface structure array is provided with a metasurface structural unit.

In one embodiment, the metasurface structural unit includes any one of a silicon-on-insulator (SOI) material, an SiO₂—Si material, and a GaAs material.

In one embodiment, the metasurface structural unit includes any one of a cylindrical structure and a prism structure.

In one embodiment, the type of the metasurface module includes a reflection type or a transmission type.

In a second aspect, the present disclosure provides a photoelectric device, wherein the photoelectric device includes the programmable structured light generator according to any one of the first aspect.

In one embodiment, the photoelectric device is a pair of virtual reality glasses, and a left-side spectacle frame and a right-side spectacle frame of the virtual reality glasses are respectively provided with the programmable structured light generator.

In a third aspect, the present disclosure provides a manufacturing method of a programmable structured light generator, wherein the manufacturing method is used for the metasurface module according to any one of the first aspect, and the manufacturing method includes: determining the material and shape of the metasurface structural unit, and performing electromagnetic simulation scanning on geometric parameters of the metasurface structural unit, so as to obtain a relationship distribution diagram of optical parameters and geometric parameters of the metasurface structural unit, wherein the optical parameters include reflectivity and reflection phase, or transmittance and transmission phase; according to the relationship distribution diagram, selecting metasurface structural units with different geometric parameters in an area with reflectivity or transmittance greater than a preset value, wherein discretization phases corresponding to the metasurface structural units with different geometric parameters cover 0-2 π; constructing a structured light speckle dot matrix, and performing iteration by means of a hologram phase extraction algorithm, so as to obtain a pure-phase holographic distribution; and matching the pure-phase holographic distribution with the discretization phases of the metasurface structural units, so as to obtain a micro-nano processable metasurface size parameter, and generating the metasurface module.

In one embodiment, the hologram phase extraction algorithm includes a Gerchberg-Saxton algorithm or a gradient descent algorithm.

In one embodiment, the matching mode includes at least one of propagation phase (modulating the phase by changing the length and width of the metasurface structural units) matching and Pancharatnam-Berry (PB) phase (modulating the phase by changing the rotation angle of the metasurface structural units) matching.

As can be seen from the above technical solutions, the present disclosure has the following advantages:

The present disclosure provides a programmable structured light generator, a photoelectric device having same, and a manufacturing method. The programmable structured light generator can accurately control the light spot position coding of the VCSEL array by means of the programmable controller, thereby being efficient and flexible; then, the metasurface module located on the emitted light focal plane path can project the programmable structured light speckle dot matrix pattern in the far field, and the copy expansion coding of a single point in the structured light speckle dot matrix pattern are in one-to-one correspondence with the light spot position coding in the VCSEL array, thereby greatly improving the calculation precision and having high reliability; and meanwhile, the metasurface module is also beneficial to ultra-thinness and miniaturization of the structured light generator, so that the application range is wide.

### BRIEF DESCRIPTION OF THE DRAWINGS

Other features, objectives and advantages of the present disclosure will become more apparent by reading the detailed description of non-restrictive embodiments with reference to the following drawings:

Other features, objectives and advantages of the present disclosure will become more apparent by reading the detailed description of non-restrictive embodiments with reference to the following drawings:

FIG. 1 is a structural block diagram of a programmable structured light generator provided in an embodiment of the present disclosure;

FIG. 2 is a schematic diagram of an 8×8 vertical cavity surface emitting laser array provided in an embodiment of the present disclosure;

FIG. 3 is a schematic diagram of a light spot position coding of a VCSEL array provided in an embodiment of the present disclosure;

FIG. 4 is a schematic diagram of a light spot position coding of a VCSEL array and a corresponding far-field programmable structured light speckle dot matrix pattern provided in an embodiment of the present disclosure;

FIG. 5 is a schematic diagram of an SOI metasurface structural unit based on propagation phase provided in an embodiment of the present disclosure;

FIG. 6 is a schematic diagram of an SOI metasurface structural unit based on PB phase provided in an embodiment of the present disclosure;

FIG. 7A to 7C are schematic diagrams of a programmable structured light generator based on a reflection type provided in an embodiment of the present disclosure;

FIG. 8A to 8C are schematic diagrams of a programmable structured light generator based on a transmission type provided in an embodiment of the present disclosure;

FIG. 9 is a structural block diagram of a photoelectric device provided in an embodiment of the present disclosure;

FIG. 10 is a schematic diagram of a programmable structured light generator for detecting an actual object depth provided in an embodiment of the present disclosure;

FIG. 11 is a schematic diagram of a programmable structured light generator for performing eyeball tracking detection on virtual reality glasses provided in an embodiment of the present disclosure;

FIG. 12 is a schematic flowchart of a manufacturing method of a programmable structured light generator provided in an embodiment of the present disclosure;

FIG. 13 is a relationship distribution diagram of reflectivity and geometric parameters of an SOI reflection-type metasurface structural unit provided in an embodiment of the present disclosure;

FIG. 14 is a relationship distribution diagram of a reflection phase and geometric parameters of an SOI reflection-type metasurface structural unit provided in an embodiment of the present disclosure;

FIG. 15 is a schematic diagram of a reflectivity and discretization phase distribution of a 16-order metasurface structural units capable of covering 0-2π in an SOI reflection-type metasurface structural unit provided in an embodiment of the present disclosure;

FIG. 16 is a fabricated SOI reflection metasurface scanning electron microscope image based on propagation phase provided in an embodiment of the present disclosure; and

FIG. 17 is a processed SOI reflection metasurface scanning electron microscope image based on PB phase provided in an embodiment of the present disclosure.

### REFERENCE SIGNS

1—programmable structured light generator, 11—laser module, 111—programmable controller, 112—vertical cavity surface emitting laser array, 12—collimation module, 13—metasurface module, 131—programmable structured light speckle dot matrix pattern, 132—metasurface structure array, 2—object for depth detection, 3—photoelectric device, 4—infrared camera, 5—virtual reality glasses, 6—virtual reality glasses wearer.

### DETAILED DESCRIPTION

In order to enable those skilled in the art to better understand the solutions of the present disclosure, a clear and complete description of technical solutions in the embodiments of the present disclosure will be given below, in combination with the drawings in the embodiments of the present disclosure. Apparently, the embodiments described below are merely a part, but not all, of the embodiments of the present disclosure. All of other embodiments, obtained by those of ordinary skill in the art based on the embodiments in the present disclosure without any creative effort, fall into the protection scope of the present disclosure.

The terms “first”, “second”, “third”, “fourth” and the like (if present) in the specification, claims and the above drawings of the present disclosure are used for distinguishing similar objects, and are not necessarily used for describing a specific sequence or precedence order. It should be understood that the data used in this way may be interchanged under appropriate circumstances, so that the embodiments of the present disclosure described herein may be implemented in a sequence other than those illustrated or described herein.

In addition, the terms “including” and “having”, and any variations thereof are intended to cover non-exclusive inclusions, for example, processes, methods, systems, products or devices including a series of steps or module are not necessarily limited to those clearly listed steps or modules, but may include other steps or modules that are not clearly listed or are inherent to these processes, methods, products or devices.

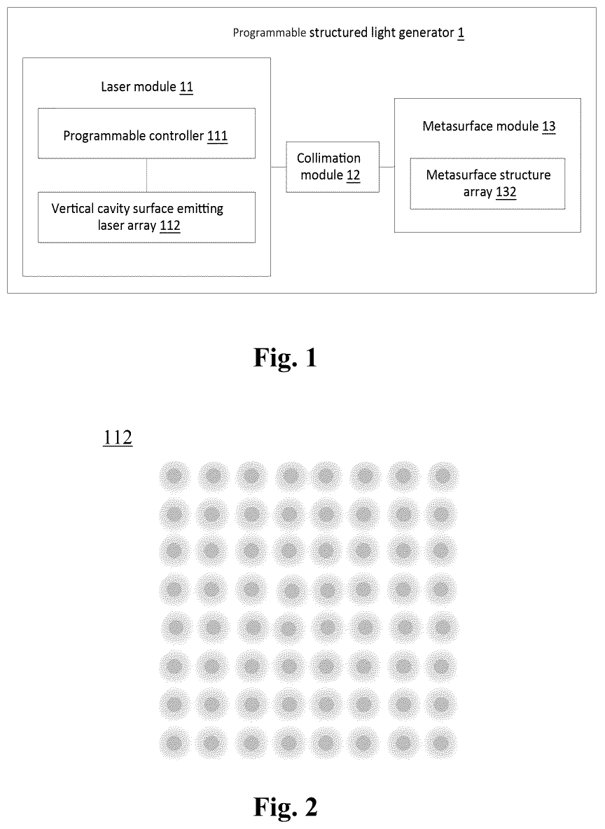

For ease of understanding and description, a programmable structured light generator, a photoelectric device having same, and a manufacturing method provided in the embodiments of the present disclosure are described in detail below from FIG. 1 to FIG. 17.

Please refer to FIG. 1, it is a structural block diagram of a programmable structured light generator provided in an embodiment of the present disclosure, the programmable structured light generator 1 includes a laser module 11, a collimation module 12 disposed on a light outlet of a VCSEL array, and a metasurface module 13 disposed on an emergent light focal plane path.

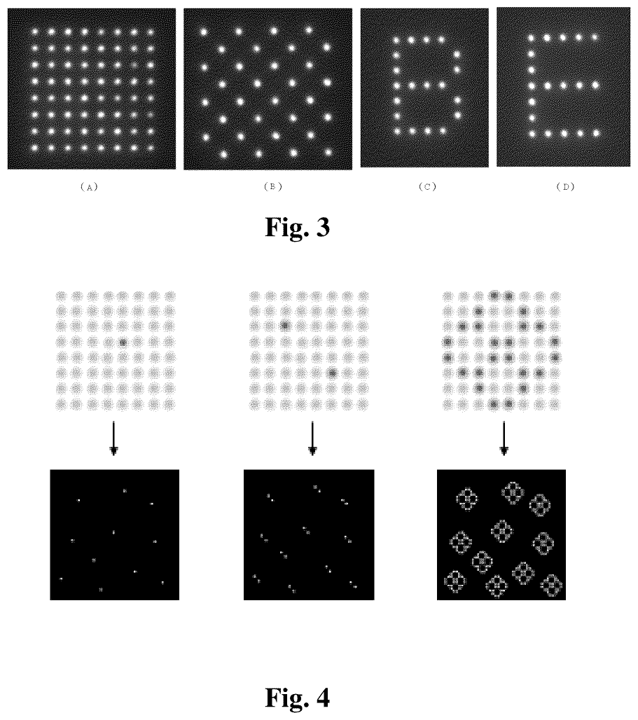

The laser module 11 includes, but is not limited to, a programmable controller 111 and an individually addressable vertical cavity surface emitting laser array 112, wherein the programmable controller 111 may control light spot position codes of the VCSEL array 112, for example, an 8×8 vertical cavity surface emitting laser array 112 shown in FIG. 2, which is connected and assembled with a driving circuit in a wire bonding mode, and these VCSELs share the same cathode, but anodes are separated for on-off switching, so as to realize an individually addressable control function, and the programmable controller 111 is used for performing pre-coding and real-time coding on any one or more VCSELs in the array, that is, controlling the on-off conditions of the VCSELs, so as to realize the light spot position coding shown in FIG. 3, which are sequentially light spot coding patterns composed of 64, 32, 20 and 19 VCSELs in the 8×8 array from left to right. The collimation module 12 may collimate the emergent light of the VCSEL array 112; and the metasurface module 13 may project a programmable structured light speckle dot matrix pattern 131 in a far field, and copy expansion codes of a single point in the structured light speckle dot matrix pattern 131 are in one-to-one correspondence with the light spot position coding in the VCSEL array 112, for example, as shown in FIG. 4, that is, the programmable controller 111 controls the on-off conditions of different positions of the VCSEL array, so that light spot positions projected on a metasurface can be coded and controlled, and the programmable structured light speckle dot matrix pattern 131 is projected in the far field.

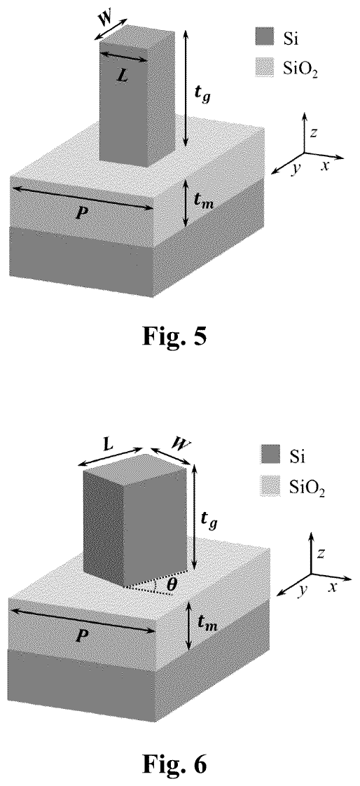

For example, in the embodiment of the present disclosure, the metasurface module 13 may include a metasurface structure array 132, and the metasurface structure array 132 is provided with metasurface structural units. For example, the metasurface structural unit includes, but is not limited to, any one of a silicon-on-insulator (SOI), a SiO2-Si material, and a GaAs material. The metasurface structural unit includes any one of a cylindrical structure and a prism structure, wherein the prism structure may be a rectangle, a pentagonal prism, a hexagonal prism and the like, as shown in FIG. 5 and FIG. 6, which respectively correspond to an SOI metasurface structural unit based on a propagation phase and an SOI metasurface structural unit based on PB phase, wherein L represents the length of a nanorod, W represents the width of the nanorod, tg represents the height of the nanorod, tm represents the thickness of an SiO2 intermediate layer of SOI, P represents a lattice constant of the structural unit and θ represents a rotation angle of the nanorod.

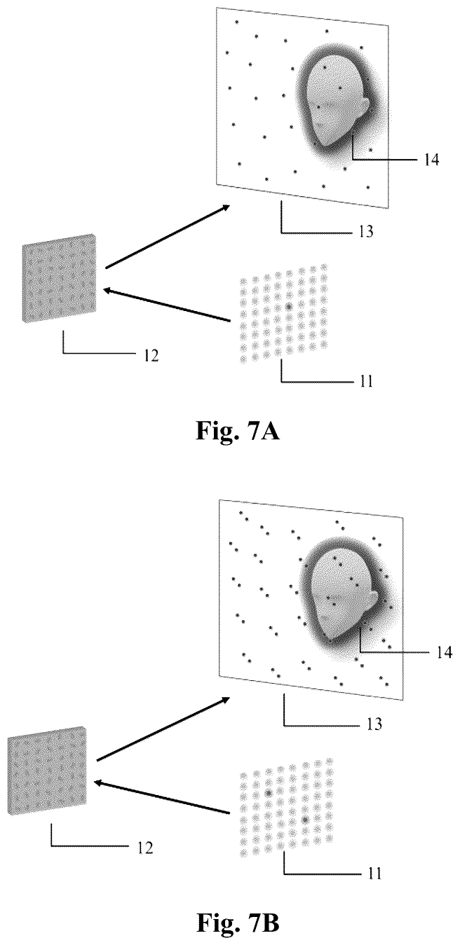

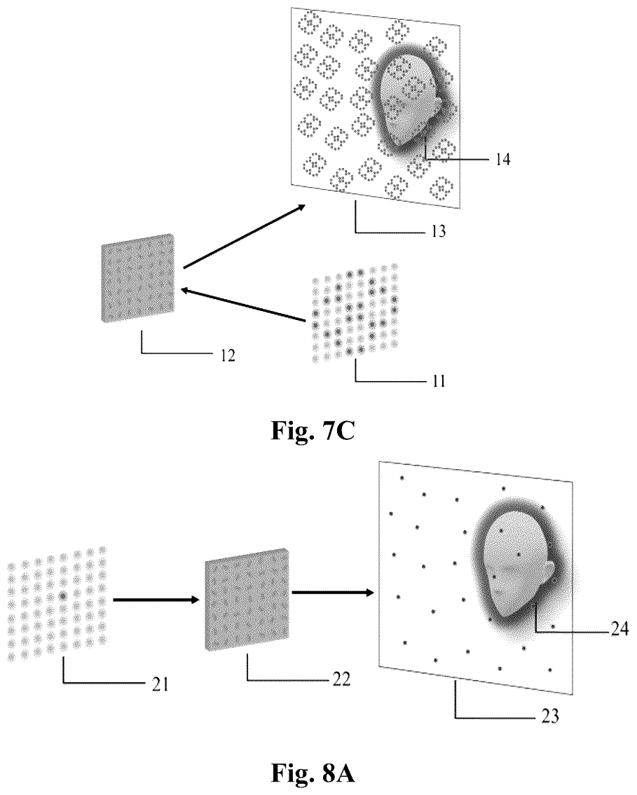

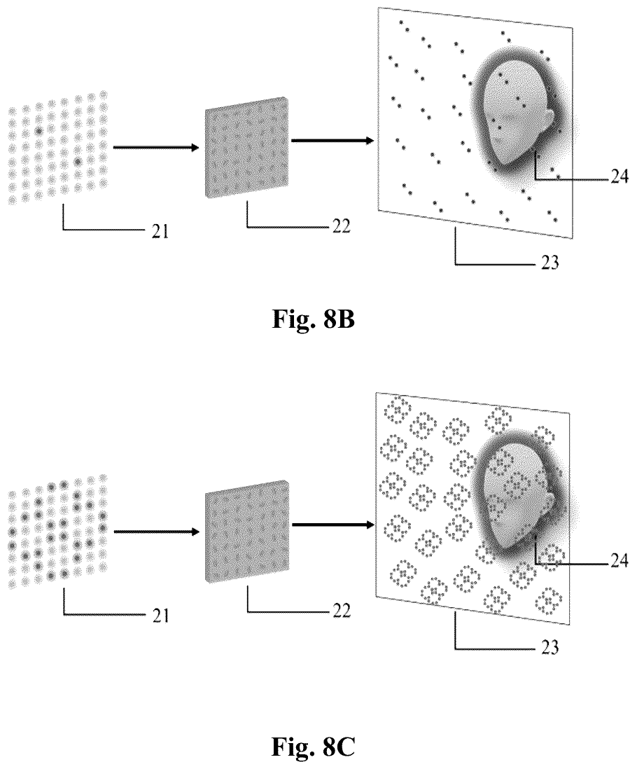

In one embodiment, the type of the metasurface module 13 in the embodiment of the present disclosure includes a reflection type or a transmission type, for example, as shown in FIG. 7A to 7C and FIG. 8A to 8C, which are respectively a programmable structured light generator based on the reflection type and a programmable structured light generator based on the transmission type, wherein 2 represents an object for depth detection.

The programmable structured light generator provided in the embodiment of the present disclosure can accurately control the light spot position coding of the VCSEL array by means of the programmable controller, thereby being efficient and flexible; then, the metasurface module located on the emitted light focal plane path can project the programmable structured light speckle dot matrix pattern in the far field, and the copy expansion coding of a single point in the structured light speckle dot matrix pattern are in one-to-one correspondence with the light spot position coding in the VCSEL array, thereby greatly improving the calculation precision and having high reliability; and meanwhile, the metasurface module is also beneficial to ultra-thinness and miniaturization of the structured light generator, so that the application range is wide.

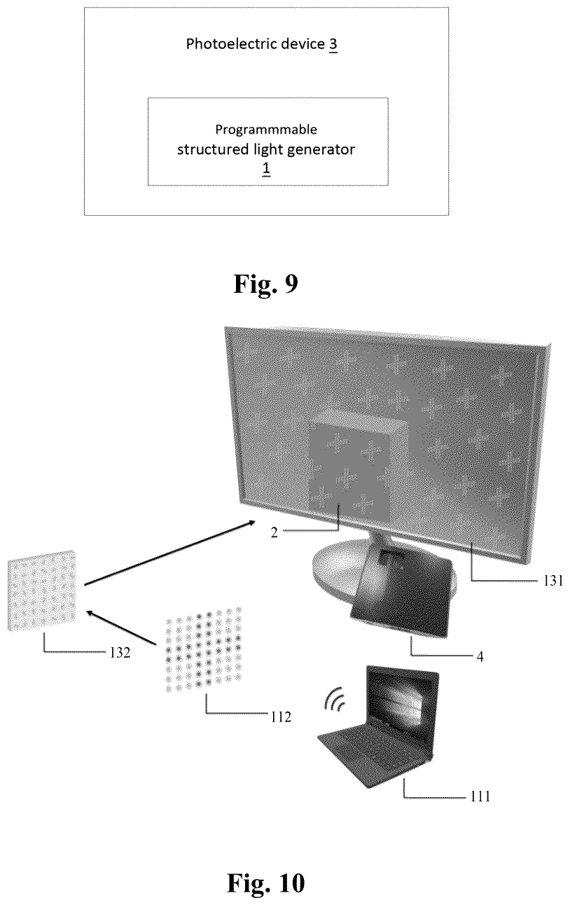

As another aspect, an embodiment of the present disclosure provides a photoelectric device. Please refer to FIG. 9, it is a structural block diagram of a photoelectric device provided in an embodiment of the present disclosure, and the photoelectric device 3 includes the programmable structured light generator 1 of the embodiment corresponding to FIG. 1 to FIG. 8C.

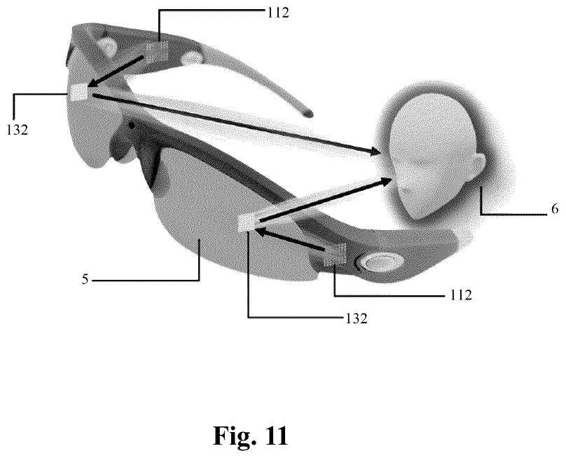

In an actual use process, in the embodiment of the present disclosure, a three-dimensional space of a measured target object is marked by using the programmable structured light speckle dot matrix pattern, then an infrared camera receives a reflected structured light speckle pattern, and the three-dimensional morphology of the measured object is detected by calculating the speckle deformation condition of structured light, wherein the calculation mode includes, but is not limited to, constructing a triangular relationship according to projection transformation, etc. For example, as shown in FIG. 10, it is a schematic diagram of the programmable structured light generator for detecting an actual object depth provided in an embodiment of the present disclosure, wherein 4 represents the infrared camera in FIG. 10. As another example, as shown in FIG. 11, it is a schematic diagram of a programmable structured light generator for performing eyeball tracking detection on virtual reality glasses provided in an embodiment of the present disclosure, wherein 5 represents a pair of virtual reality (Virtual Reality, VR) glasses, 6 represents a VR glasses wearer, and a left-side spectacle frame and a right-side spectacle frame of the VR glasses are respectively provided with the programmable structured light generator 1, therefore the programmable structured light speckle dot matrix pattern is used for tracking eyeball movement, and non-inductive control of smart devices and information by the eyeball movement is realized by means of structured light calculation, so that the operation is more convenient.

According to the photoelectric device provided in the embodiment of the present disclosure, the programmable structured light generator in the photoelectric device can accurately control the light spot position coding of the VCSEL array by means of the programmable controller, thereby being efficient and flexible; then, the metasurface module located on the emitting light focal plane path can project the programmable structured light speckle dot matrix pattern in the far field, and the copy expansion coding of a single point in the structured light speckle dot matrix pattern are in one-to-one correspondence with the light spot position coding in the VCSEL array, thereby greatly improving the calculation precision and having high reliability; and meanwhile, the metasurface module is also beneficial to ultra-thinness and miniaturization of the structured light generator, so that the application range is wide.

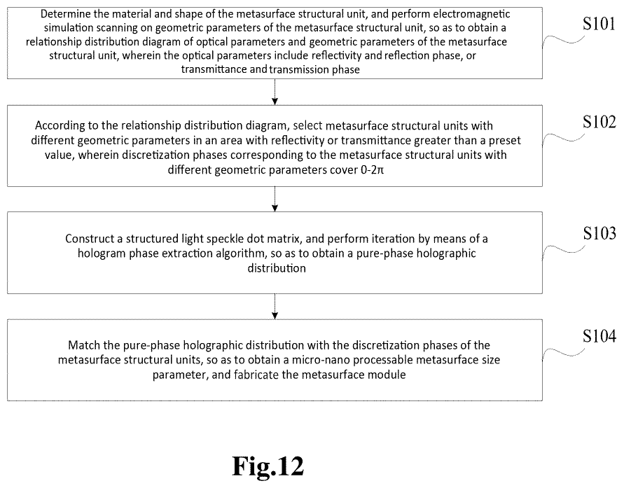

As yet another aspect, an embodiment of the present disclosure provides a manufacturing method of a programmable structured light generator, wherein the manufacturing method may be used for the metasurface module 13 of the embodiment corresponding to FIG. 1 to FIG. 8, and as shown in FIG. 12, the manufacturing method specifically includes the following steps:

At a step S101, determining the material and shape of the metasurface structural unit, and performing electromagnetic simulation scanning on geometric parameters of the metasurface structural unit, so as to obtain a relationship distribution diagram of optical parameters and geometric parameters of the metasurface structural unit, wherein the optical parameters include reflectivity and reflection phase, or transmittance and transmittance phase.

For example, in the embodiment of the present disclosure, metasurface design may be performed by using semiconductor materials such as SOL SiO2-Si and GaAs. Taking an SOI reflection metasurface as an example, as shown in FIG. 5, the metasurface structural unit includes a top monocrystalline silicon etching layer, a silicon dioxide intermediate layer and a thicker bottom silicon substrate layer, which may realize medium isolation of components in an integrated circuit, the manufactured integrated circuit also has the advantages of small parasitic capacitance, high integration density, simple process and the like, and has good compatibility with the mature semiconductor industry.

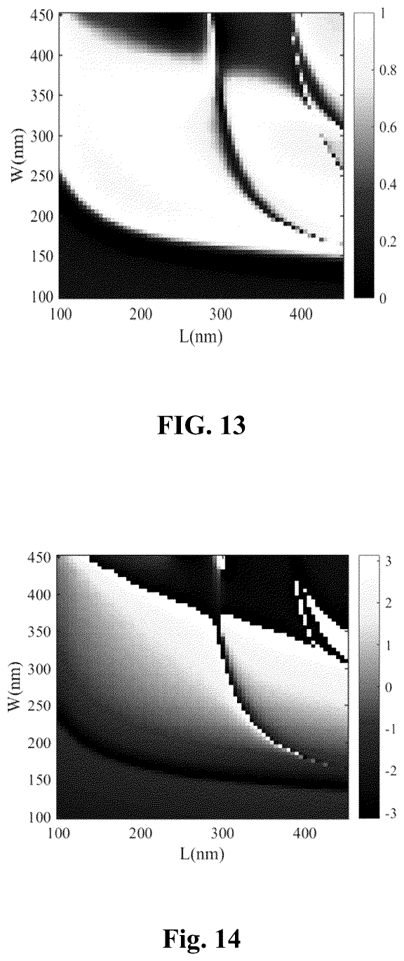

Further, in the embodiment of the present disclosure, length and width parameters of an SOI reflection metasurface unit cell in FIG. 5 are scanned by using finite difference time-domain (FDTD) electromagnetic simulation software, that is, it is set that the background refractive index of the environment is 1, the lattice constant P is 500 nm, the height tg of nanorods is 300 nm, the thickness tm of the silicon dioxide intermediate layer is 3 μm, and 940 nm light source is used as incident light, two-dimensional scanning is performed on the length L and the width W of the nanorod within a scanning range of 100 nm to 450 nm, so as to obtain a relationship distribution diagram of the reflectivity and the geometric parameters of the SOI reflection metasurface structural unit as shown in FIG. 13 and a relationship distribution diagram of a reflection phase and the geometric parameters of the SOI reflection-type metasurface structural unit as shown in FIG. 14, wherein the reflectivity range is 0 to 1, the unit of the reflection phase is radian, and the range thereof is −π to π. As can be seen from the figures, full coverage of the reflection phase in the range of 2π can be completely realized by adjusting the length and width parameters of the unit cell.

At a step S102, according to the relationship distribution diagram, selecting metasurface structural units with different geometric parameters in an area with reflectivity or transmittance greater than a preset value, wherein discretization phases corresponding to the metasurface structural units with different geometric parameters cover 0-2π.

For example, in the embodiment of the present disclosure, the range of 0-2π may be discretized into 16-order phases with equal distances, in FIG. 5, 16 groups of metasurface structural units with different length and width parameters are selected from a high-reflectivity area in which the reflectivity of the SOI reflection-type metasurface structural unit is greater than 0.8, so that 16-order discretization phases covering 0-2π can be realized. Of course, the order may also be other numerical values, which is not limited in the embodiment of the present disclosure.

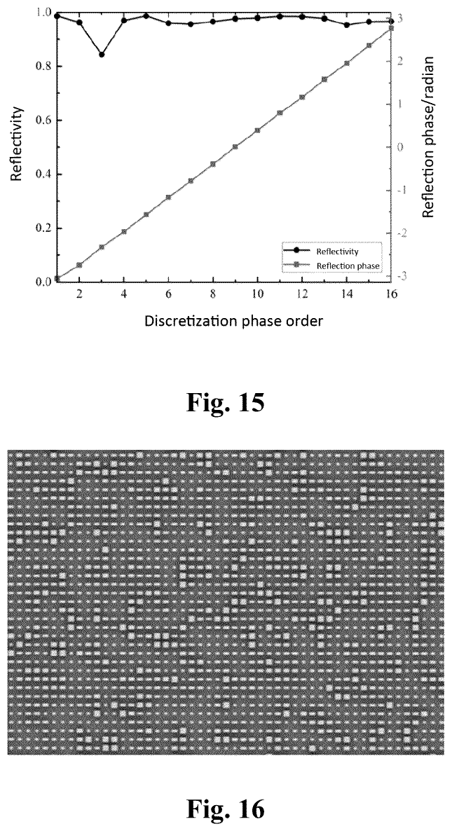

Further, as shown in FIG. 15, a curve composed of dark-color circular points and light-color square points respectively represents the reflectivity and discretization phase distributions of the 16-order metasurface structural units. As can be seen from the figure, the reflectivity of most of the selected structural units is greater than 95%, and the phase coverage in the range of 2π can be basically realized.

At a step S103, constructing a structured light speckle dot matrix, and performing iteration by means of a hologram phase extraction algorithm, so as to obtain a pure-phase holographic distribution.

For example, in the embodiment of the present disclosure, iteration may be performed by means of hologram phase extraction algorithms such as a Gerchberg-Saxton (GS) algorithm and a gradient descent algorithm, so as to obtain the pure-phase holographic distribution corresponding to a structured light speckle dot matrix image. The structured light speckle dot matrix may be random or pseudo-random, etc.

At a step S104, matching the pure-phase holographic distribution with the discretization phases of the metasurface structural units, so as to obtain a micro-nano processable metasurface size parameter, and fabricating the metasurface module.

For example, in the embodiment of the present disclosure, the pure-phase holographic distribution may be matched by using the propagation phase (that is, phase modulation is performed by changing the length and width of the nanorod) in FIG. 5 (propagation phase matching) or the PB phase (that is, phase modulation is performed by changing the rotation angle of the nanorod) in FIG. 6 (PB phase matching). According to the basic principle of PB-Phase, nanorod units with the same length (L), width (W) and height (tg) and different rotation angles θ(x, y) may be used to perform phase modulation, that is, for the PB-Phase metasurface, the length (L), width (W) and height (tg) of the nanorod unit are fixed, and phase modulation is only performed on the rotation angle θ(x, y) of the nanorod unit, so as to realize a propagation geometric phase φ(x, y), the relationship therebetween is θ(x,y)=½·φ(x,y), that is, the rotation angle θ(x, y) of the nanorod in the range of 0-180° on an incidence plane can realize the propagation geometric phase φ(x, y) in the range of 0-360° on a reflection plane.

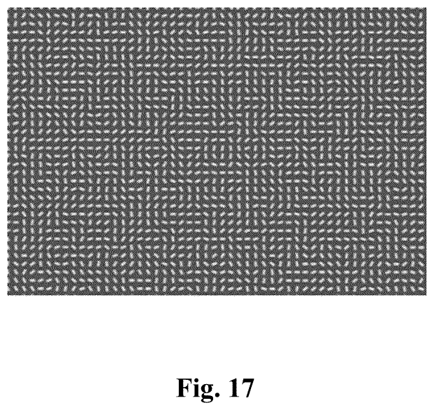

Further, in the embodiment of the present disclosure, the propagation phase in FIG. 5 or the PB phase in FIG. 6 may be matched with the pure-phase holographic distribution, so as to generate the final micro-nano processable metasurface size parameters, and micro-nano fabrication is performed on the designed metasurface by means of standard electron beam lithography (EBL) in combination with lift-off process, so as to obtain the fabricated metasurface structures, which are respectively shown in FIG. 16 and FIG. 17, wherein FIG. 16 is a scanning electron microscope (SEM) image of the fabricated SOI reflection metasurface based on propagation phase, and FIG. 17 is the SEM image of the fabricated SOI reflection metasurface based on PB phase.

It should be noted that, in the present embodiment, description of the same steps and the same content in the other embodiments may refer to the description in the other embodiments, and thus details are not described herein again.

According to the manufacturing method of the programmable structured light generator provided in the embodiment of the present disclosure, the programmable structured light generator manufactured by the manufacturing method can accurately control the light spot position coding of the VCSEL array by means of the programmable controller, thereby being efficient and flexible; then, the metasurface module located on the emitted light focal plane path can project the programmable structured light speckle dot matrix pattern in the far field, and the copy expansion coding of a single point in the structured light speckle dot matrix pattern are in one-to-one correspondence with the light spot position coding in the VCSEL array, thereby greatly improving the calculation precision and having high reliability; and meanwhile, the metasurface module is also beneficial to ultra-thinness and miniaturization of the structured light generator, so that the application range is wide.

The above embodiments are merely used for illustrating the technical solutions of the present disclosure, rather than limiting the same. Although the present disclosure has been described in detail with reference to the foregoing embodiments, it should be understood by those of ordinary skill in the art that, they may still make modifications to the technical solutions recorded in the foregoing embodiments, or perform equivalent replacements on some technical features, and these modifications or replacements do not make the essence of the corresponding technical solutions depart from the spirit and scope of the technical solutions of various embodiments of the present disclosure.

What is claimed is:

1. A programmable structured light generator, wherein the programmable structured light generator comprises:
a laser module, wherein the laser module comprises a programmable controller and an individually addressable VCSEL array, and the programmable controller is used for controlling light spot position coding of the VCSEL array;
a collimation module, disposed at a light source emitter of the VCSEL array, wherein the collimation module is used for collimating emitted light of the VCSEL array; and
a metasurface module, disposed on an emitted light focal plane path, wherein the metasurface module is used for projecting a programmable structured light speckle dot matrix pattern in a far field, and copy expansion coding of a single point in the structured light speckle dot matrix pattern are in one-to-one correspondence with the light spot position coding in the VCSEL array.

2. The programmable structured light generator according to claim 1, wherein the metasurface module comprises a metasurface structure array and the metasurface structure array is provided with a metasurface structural unit.

3. The programmable structured light generator according to claim 2, wherein the metasurface structural unit comprises any one of a SOI material, a SiO₂—Si material, or a GaAs material.

4. The programmable structured light generator according to claim 2, wherein the metasurface structural unit comprises any one of a cylindrical structure or a prism structure.

5. The programmable structured light generator according to claim 1, wherein the type of the metasurface module comprises a reflection type or a transmission type.

6. A photoelectric device, wherein the photoelectric device comprises the programmable structured light generator according to claim 1.

7. The photoelectric device according to claim 6, wherein the photoelectric device is a pair of virtual reality glasses, and a left-side spectacle frame and a right-side spectacle frame of the virtual reality glasses are respectively provided with the programmable structured light generator.

8. The photoelectric device according to claim 6, wherein the metasurface module comprises a metasurface structure array and the metasurface structure array is provided with a metasurface structural unit.

9. The photoelectric device according to claim 8, wherein the metasurface structural unit comprises any one of a SOI material, a SiO₂—Si material, or a GaAs material.

10. The photoelectric device according to claim 8, wherein the metasurface structural unit comprises any one of a cylindrical structure or a prism structure.

11. The photoelectric device according to claim 6, wherein the type of the metasurface module comprises a reflection type or a transmission type.

12. A manufacturing method of a programmable structured light generator, wherein the manufacturing method is used for the metasurface module according to claim 2, the manufacturing method comprising:
determining the material and shape of the metasurface structural unit, and performing electromagnetic simulation scanning on geometric parameters of the metasurface structural unit, so as to obtain a relationship distribution diagram of optical parameters and the geometric parameters of the metasurface structural unit, wherein the optical parameters comprise a reflectivity and reflection phase, or a transmittance and transmission phase;
according to the relationship distribution diagram, selecting metasurface structural units with different geometric parameters in an area with reflectivity or transmittance greater than a preset value, wherein discretization phases corresponding to the metasurface structural units with different geometric parameters cover 0-2π;
constructing a structured light speckle dot matrix, and performing iteration by means of a hologram phase extraction algorithm, so as to obtain a pure-phase holographic distribution; and
matching the pure-phase holographic distribution with the discretization phases of the metasurface structural units, so as to obtain a micro-nano processable metasurface size parameter and to fabricate the metasurface module.

13. The manufacturing method according to claim 12, wherein the hologram phase extraction algorithm comprises a Gerchberg-Saxton algorithm or a gradient descent algorithm.

14. The manufacturing method according to claim 12, wherein matching the pure-phase holographic distribution with the discretization phases of the metasurface structural units comprises at least one of propagation phase matching or Pancharatnam-Berry phase matching.
